(19) United States
(12) Patent Application Publication
(10) Pub. No.: US 2015/0001409 A1
(43) Pub. Date: Jan. 1, 2015

(54) Optical Assembly

(71) Applicant: Robert Bosch GmbH, Stuttgart (DE)

(72) Inventors: Richard Fix, Gerlingen (DE); Patrick Sonstroem, Herrenberg (DE); Michael Kneissl, Berlin (DE); Markus Weyers, Wildau (DE)

(21) Appl. No.: 14/317,518

(22) Filed: Jun. 27, 2014

(30) Foreign Application Priority Data
Jun. 27, 2013 (DE) 10 2013 212 372.8

(51) Int. Cl. H01L 33/58; G01N 21/55

(52) U.S. Cl. CPC H01L 33/58; G01N 21/55
USPC 250/372; 257/98

(57) ABSTRACT

An optical assembly includes at least one optical semiconductor component which is configured for electroluminescence. The optical semiconductor component is further configured to generate electromagnetic radiation distributed around a radiation maximum. At least one short-pass edge filter is positioned in a beam path of the electromagnetic radiation. A limiting wavelength of the short-pass edge filter is greater than a wavelength of the radiation maximum by a predefined amount.

This application claims priority under 35 U.S.C. §119 to patent application no. DE 10 2013 212 372.8, filed on Jun. 27, 2013 in Germany, the disclosure of which is incorporated herein by reference in its entirety.

### BACKGROUND

Optical assemblies comprising optical semiconductor components designed for electroluminescence are known. Optical semiconductor components can be embodied as light-emitting diodes by means of which electromagnetic radiation distributed around a radiation maximum can be generated.

The distribution of electromagnetic radiation generated by an optical semiconductor component around a radiation maximum is governed, in particular, by the respective state densities in the conduction band and in the valence band of the respective material in which electromagnetic radiation is intended to be generated, and by the respective occupation of the possible states by charge carriers. The occupation of the possible states can be described by Fermi-Dirac statistics and is temperature-dependent. The temperature dependence of the occupation of possible states has the effect that the distribution of the electromagnetic radiation generated by an optical semiconductor element around a radiation maximum becomes wider as the temperature increases. A widening of electromagnetic radiation generated by an optical semiconductor component with a layer construction can additionally be governed by layer thickness variations and inhomogeneities in the composition of individual layers.

### SUMMARY

The disclosure relates to an optical assembly comprising at least one optical semiconductor component which is designed for electroluminescence and by means of which electromagnetic radiation distributed around a radiation maximum can be generated, characterized by at least one short-pass edge filter which is arranged in the beam path of the electromagnetic radiation and the limiting wavelength of which is greater than the wavelength of the radiation maximum by a predefinable amount.

By means of the short-pass edge filter, the electromagnetic radiation generated by the optical semiconductor component is filtered in such a way that electromagnetic radiation having a wavelength that is greater than the limiting wavelength of the short-pass edge filter is removed from the spectrum of the electromagnetic radiation generated by the optical semiconductor component. What is thereby achieved is that the electromagnetic radiation emitted by the optical assembly no longer contains this filtered-out longer-wave spectral range.

Exclusive generation of electromagnetic radiation in the region of the p-n junction of optical semiconductor components basically cannot be realized from a technical standpoint. Instead, the electromagnetic radiation generated by an optical semiconductor component usually contains longer-wave spectral components, generated in particular by defect luminescence, which are caused for example by generation of electromagnetic radiation in the p-type portion of an optical semiconductor component. This usually undesired generation of longer-wave electromagnetic radiation is governed in particular by the customary layer construction of an optical semiconductor component and the respective quality of the materials used for the layers. The use of a short-pass edge filter according to the disclosure enables said longer-wave spectral component to be removed from the electromagnetic radiation generated by an optical semiconductor component. As a result, it is possible to achieve a very high spectral purity with regard to the electromagnetic radiation generated by an optical semiconductor component.

In accordance with one advantageous configuration, the short-pass edge filter is integrated into the optical semiconductor component. As a result, a space-saving, compact construction is imparted to the optical assembly.

According to an alternative advantageous configuration, the short-pass edge filter is arranged at a further optical element of the optical assembly. By way of example, a lens, an optical window, a mirror, a fiber component or the like is appropriate as the optical element.

A further advantageous configuration provides for the short-pass edge filter to be embodied as an absorption filter, as a reflection filter or as a Fabry-Perot interferometer. A reflection filter can be embodied for example as a dielectric mirror, in particular as a Bragg mirror (“Distributed Bragg Reflector”; DBR). This has the advantage that the limiting wavelength of the short-pass edge filter does not depend on the respectively provided temperature as greatly as may be the case for an absorption filter. A stabilization of the wavelength range of the electromagnetic radiation emitted by a correspondingly configured optical assembly is achieved as a result. A short-pass edge filter embodied as a Fabry-Perot interferometer allows only electromagnetic radiation having a very narrow bandwidth to pass through, depending on the setting of its resonator.

It is furthermore deemed to be advantageous if the limiting wavelength of the short-pass edge filter is less than the wavelength which is greater than the wavelength of the radiation maximum and at which the radiation intensity of the electromagnetic radiation generated by the optical semiconductor component has fallen to half of the radiation intensity of the radiation maximum. What can thereby be achieved is that electromagnetic radiation which is generated by the optical semiconductor component and the wavelength of which is greater than the wavelength of the radiation maximum of the electromagnetic radiation is to the greatest possible extent not emitted by the optical assembly.

According to a further advantageous configuration, the optical assembly comprises at least one long-pass edge filter which is arranged in the beam path of the electromagnetic radiation and the limiting wavelength of which is less than the wavelength of the radiation maximum by a predefinable amount. By means of the long-pass edge filter, the electromagnetic radiation generated by the optical semiconductor component is filtered in such a way that electromagnetic radiation whose wavelength is less than the limiting wavelength of the long-pass edge filter is removed from the spectrum of the electromagnetic radiation generated by the optical semiconductor element. What is thereby achieved is that the electromagnetic radiation emitted by the optical assembly no longer contains the filtered-out shorter-wave spectral range. An optical assembly comprising an abovementioned short-pass edge filter and such a long-pass edge filter can be used for emitting electromagnetic radiation in a greatly delimited wavelength range. By way of example, such a wavelength range can have a width of 2 nm. As a result, a corresponding optical assembly is very well suited to spectroscopic applications, particularly since the absorption bands of many gas molecules have a width of 1 nm to 2 nm.

In accordance with a further advantageous configuration, the long-pass edge filter is integrated into the optical semiconductor component. As a result, a space-saving, compact construction is imparted to the optical assembly.

It is furthermore deemed to be advantageous if the long-pass edge filter is arranged at a further optical element of the optical assembly. In this case, too, by way of example, a lens, an optical window, a mirror, a fiber component or the like is appropriate as the optical element.

According to a further advantageous configuration, the long-pass edge filter is embodied as an absorption filter, as a reflection filter or as a Fabry-Perot interferometer. A reflection filter can be embodied for example as a dielectric mirror, in particular as a Bragg mirror (“Distributed Bragg Reflector”; DBR). This has the advantage that the limiting wavelength of the long-pass edge filter does not depend on the respectively provided temperature as greatly as may be the case for an absorption filter. A stabilization of the wavelength range of the electromagnetic radiation emitted by a correspondingly configured optical assembly is achieved as a result. Aluminum gallium nitride (AlGaN) can be used as material for the embodiment of the reflection filter or absorption filter. A long-pass edge filter embodied as a Fabry-Perot interferometer allows only electromagnetic radiation having a very narrow bandwidth to pass through, depending on the setting of its resonator.

A further advantageous configuration provides for the limiting wavelength of the long-pass edge filter to be less than the wavelength which is less than the wavelength of the radiation maximum and at which the radiation intensity of the electromagnetic radiation generated by the optical semiconductor component has fallen to half of the radiation intensity of the radiation maximum. What can thereby be achieved is that electromagnetic radiation which is generated by the optical semiconductor component and the wavelength of which is less than the wavelength of the radiation maximum of the electromagnetic radiation is to the greatest possible extent not emitted by the optical assembly.

Furthermore, it is deemed to be advantageous if the optical semiconductor component generates electromagnetic radiation in the UVC range. Precisely in the case of such optical semiconductor components which generate electromagnetic radiation in a relatively short-wave range, disturbing electromagnetic radiation in longer-wave ranges occurs, which can be effectively filtered out from the electromagnetic radiation by means of a short-pass edge filter. The optical semiconductor component can alternatively be designed for generating electromagnetic radiation in a different spectral range. By way of example, the optical semiconductor component can generate electromagnetic radiation in the visible spectral range or in the IR spectral range.

The disclosure furthermore relates to a system for detecting at least one substance in a fluid, comprising at least one optical assembly which emits electromagnetic radiation and at least one optical detector unit, characterized in that the optical assembly is embodied according to any of the abovementioned configurations or any arbitrary combination thereof. The advantages mentioned above are associated therewith. The system can be used in particular for spectroscopic purposes.

The use of at least one optical assembly comprising a short-pass edge filter and a long-pass edge filter enables the spectral width of the electromagnetic radiation emitted by the optical assembly to be optimally adapted to a relatively narrowband absorption spectrum of gas molecules, as a result of which the proportion of the emission spectrum of an optical assembly which is absorbed by a substance to be detected becomes greater and the sensitivity of a corresponding system is thus improved. With simultaneous use of a plurality of optical assemblies which emit electromagnetic radiation in different spectral ranges, the selectivity can be improved through the suitable choice of short-pass edge filters and long-pass edge filters, in particular since the spectra of the electromagnetic radiations emitted by the individual optical assemblies do not mutually overlap. It is thus possible to operate a corresponding system comprising a plurality of optical assemblies and a single optical detector unit which is sensitive over a relatively large spectral range.

The optical system can be used for detecting substances in gases and/or liquids. By way of example, the optical system can be used as an exhaust-gas sensor. Furthermore, the optical system can be used for example for detecting substances contained in a fluid in medical technology, in respiration gas analysis, in fire detection, in lab-on-a-chip applications, in ventilation systems, in climate control and in devices appertaining to consumer electronics, such as, for example, in smartphones, in games consoles or the like.

### BRIEF DESCRIPTION OF THE DRAWINGS

The disclosure is explained by way of example below on the basis of preferred exemplary embodiments with reference to the accompanying figures, wherein the features presented below can constitute an aspect of the disclosure both by themselves in each case and in various combinations with one another. In the figures:

FIG. 1: shows a schematic illustration of one exemplary embodiment of an emission spectrum of an optical semiconductor component, a transmission spectrum of a long-pass edge filter and a reflection spectrum of a short-pass edge filter,

FIG. 2: shows a schematic illustration of one exemplary embodiment of the construction of an optical assembly according to the disclosure, and

FIG. 3: shows a schematic illustration of one exemplary embodiment of a system according to the disclosure.

### DETAILED DESCRIPTION

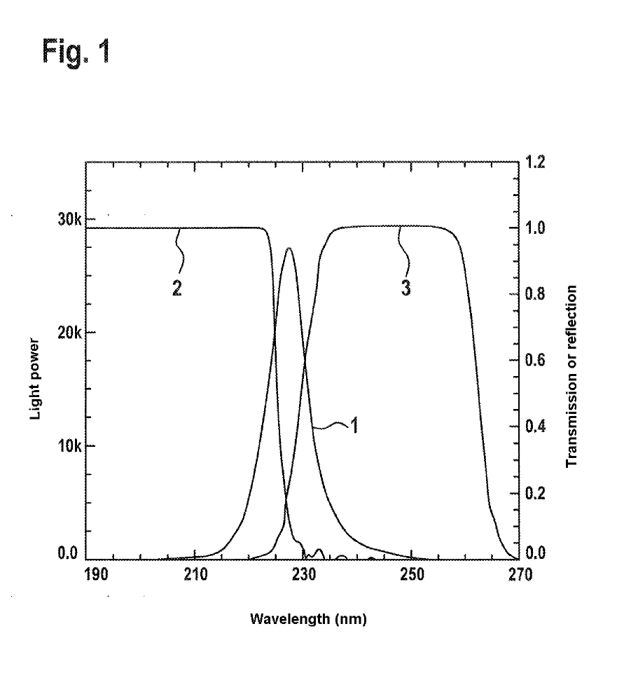

FIG. 1 shows a schematic illustration of one exemplary embodiment of an emission spectrum 1 of an optical semiconductor component designed for electroluminescence, a transmission spectrum 2 of a long-pass edge filter composed of aluminum gallium nitride, and a reflection spectrum 3 of a short-pass edge filter embodied as a dielectric mirror, wherein the long-pass edge filter and the short-pass edge filter are arranged in the beam path of the electromagnetic radiation that can be generated by the optical semiconductor component.

The electromagnetic radiation generated by the optical semiconductor component has a radiation maximum at a wavelength λₚₑₐₖ=227 nm and a full width at half maximum FWHM=9 nm, emitted as electromagnetic radiation in the UVC spectral range. The short-pass edge filter has a limiting wavelength λ_{low-pass}=230 nm, that is to say a limiting wavelength λ_{low-pass} which is greater than the wavelength λₚₑₐₖ of the radiation maximum by a predefinable amount, namely by 3 nm. Moreover, the limiting wavelength λ_{low-pass} of the short-pass edge filter is less than the wavelength which is greater than the wavelength λₚₑₐₖ of the radiation maximum and at which the radiation intensity of the electromagnetic radiation generated by the optical semiconductor component has fallen to half of the radiation intensity of the radiation maximum. The limiting wavelength λ_{cut-off}=225 nm of the long-pass edge filter is less than the wavelength λₚₑₐₖ of the radiation maximum by a predefinable amount, namely by 2 nm. Moreover, the limiting wavelength λ_{cut-off} of the long-pass edge filter is greater than the wavelength which is less than the wavelength λₚₑₐₖ of the radiation maximum and at which the radiation intensity of the electromagnetic radiation generated by the optical semiconductor component has fallen to half of the radiation intensity of the radiation maximum. As a result of the filtering of the electromagnetic radiation generated by the optical semiconductor component by means of the short-pass edge filter and the long-pass edge filter, the optical assembly emits electromagnetic radiation having a spectral width of 5 nm.

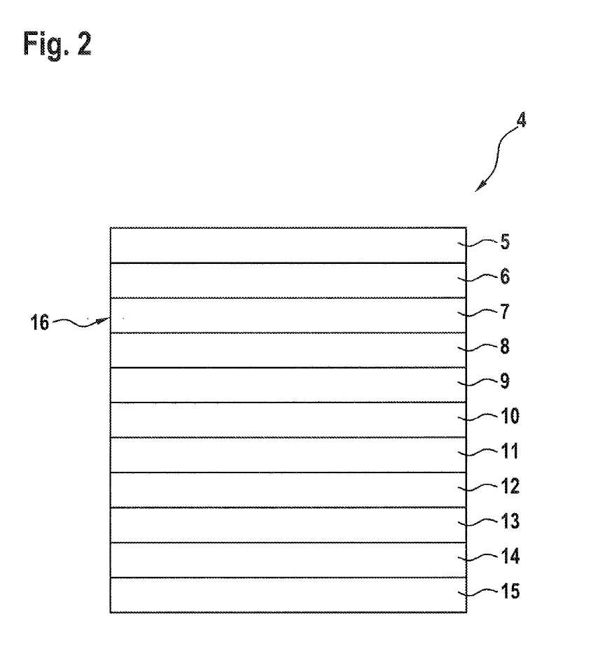

FIG. 2 shows a schematic illustration of one exemplary embodiment of the construction of an optical assembly 4 according to the disclosure. The optical assembly 4 comprises a p-type contact layer 5 composed of gallium nitride (GaN), a p-type injector layer 6 composed of aluminum gallium nitride (AlGaN), a p-type electron blocking layer 7, a barrier layer 8 and a layer 9 forming an active quantum well. The layer 9 has a bandgap wavelength λₚₑₐₖ=227 nm. The bandgap wavelengths of the electron blocking layer 7 and of the barrier layer 8 are less than λₚₑₐₖ. Furthermore, the optical assembly 4 comprises an n-type buffer layer 10 composed of aluminum gallium nitride (AlGaN), the bandgap wavelength of which is likewise less than λₚₑₐₖ The optical assembly 4 furthermore comprises a layer 11 forming a long-pass edge filter, wherein the long-pass edge filter can be embodied as an absorption filter, as a reflection filter or as a combination of reflection filter and absorption filter. The long-pass edge filter has a limiting frequency λ_{cut-off}=225 nm. The optical assembly 4 furthermore comprises a buffer layer 12 composed of aluminum gallium nitride (AlGaN), a buffer layer 13 composed of aluminum nitride (AlN) and a substrate layer 14, e.g. composed of aluminum nitride, sapphire or silicon dioxide, which is transparent to the electromagnetic radiation that can be generated by the layer 9, wherein the bandgap wavelengths of said layers 12, 13 and 14 is less than λₚₑₐₖ. Furthermore, the optical assembly 4 comprises a layer 15 forming a short-pass edge filter, wherein the short-pass edge filter is embodied as a dielectric mirror or as a Fabry-Perot interferometer. The layers 5 to 10 and 12 to 14 form the optical semiconductor component 16, into which the long-pass edge filter is integrated by way of the layer 11 and the short-pass edge filter is integrated by way of the layer 15.

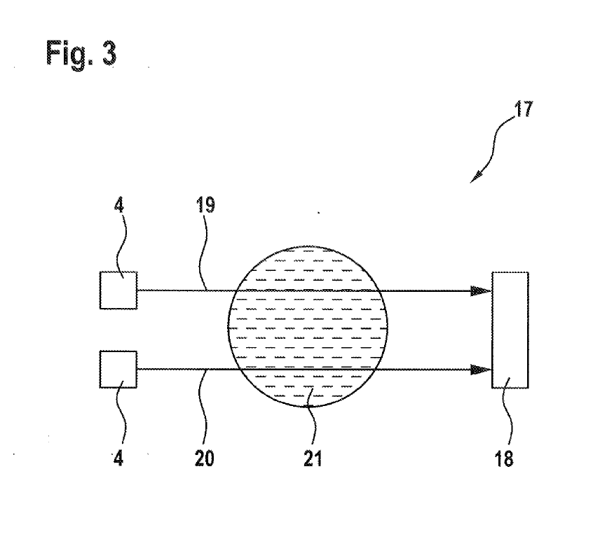

FIG. 3 shows a schematic illustration of one exemplary embodiment of a system 17 according to the disclosure for detecting at least one substance in a fluid 21. The system 17 comprises two optical assemblies 4 that emit electromagnetic radiations 19 and 20 and an optical detector unit 18. The electromagnetic radiations 19 and 20 generated by the optical assemblies 4 pass through the fluid 21 on their way to the optical detector unit 19. If the fluid 21 contains substances whose absorption bands overlap the emission spectrum of at least one optical assembly 4, the respective electromagnetic radiation is absorbed, which can be detected by means of the optical detector unit 18.

What is claimed is:

1. An optical assembly, comprising:
at least one optical semiconductor component configured for electroluminescence, and further configured to generate electromagnetic radiation distributed around a radiation maximum; and
at least one short-pass edge filter positioned in a beam path of the electromagnetic radiation, wherein a limiting radiation of the at least one short-pass edge filter is greater than a wavelength of the radiation maximum by first predefined amount.

2. The optical assembly according to claim 1, wherein the at least one short-pass edge filter is integrated into the optical semiconductor component.

3. The optical assembly according to claim 1, further comprising a further optical element, wherein the short-pass edge filter is positioned at the further optical element.

4. The optical assembly according to claim 1, wherein the at least one short-pass edge filter is an absorption filter, a reflection filter, or a Fabry-Perot interferometer.

5. The optical assembly according to claim 1, wherein:
the limiting wavelength of the at least one short-pass edge filter is less than a first further wavelength; and
the first further wavelength is greater than the wavelength of the radiation maximum, such that a radiation intensity of the electromagnetic radiation generated by the optical semiconductor component at the first further wavelength is half of a radiation intensity of the radiation maximum.

6. The optical assembly according to claim 1, further comprising at least one long-pass edge filter positioned in the beam path, wherein a limiting wavelength of the at least one long-pass edge filter is less than the wavelength of the radiation maximum by second predefined amount.

7. The optical assembly according to claim 6, wherein the at least one long-pass edge filter is integrated into the optical semiconductor component.

8. The optical assembly according to claim 6, further comprising a further optical element, wherein the at least one long-pass edge filter is positioned at the further optical element.

9. The optical assembly according to claim 6, wherein the at least one long-pass edge filter is an absorption filter, a reflection filter, or a Fabry-Perot interferometer.

10. The optical assembly according to claim 6, wherein:
the limiting wavelength of the at least one long-pass edge filter is greater than a second further wavelength; and
the second further wavelength is less than the wavelength of the radiation maximum, such that a radiation intensity of the electromagnetic radiation generated by the optical semiconductor component at the second further wavelength is half of a radiation intensity of the radiation maximum.

11. The optical assembly according to claim 1, wherein the optical semiconductor component is configured to generate radiation in the UVC range.

12. A system for detecting at least one substance in a fluid, comprising:
at least one optical detector unit; and
at least one optical assembly that is configured to emit electromagnetic radiation, and that includes:
at least one optical semiconductor component configured for electroluminescence, and further configured to generate electromagnetic radiation distributed around a radiation maximum; and
at least one short-pass edge filter positioned in a beam path of the electromagnetic radiation, wherein a limiting radiation of the at least one short-pass edge filter is greater than a wavelength of the radiation maximum by first predefined amount.
